(19) United States
(12) Patent Application Publication
(10) Pub. No.: US 2016/0233371 A1
(43) Pub. Date: Aug. 11, 2016

(54) IR PLANAR ANTENNA-COUPLED METAL-INSULATOR-METAL RECTIFIER

(71) Applicant: AMI Research & Development, LLC, Windham, NH (US)

(72) Inventors: John T. Apostolos, Lyndeborough, NH (US); William Mouyos, Windham, NH (US); Patricia Bodan, Amherst, NH (US); Milton Feng, Champaign, IL (US); Benjamin McMahon, Nottingham, NH (US)

(21) Appl. No.: 14/845,376

(22) Filed: Sep. 4, 2015

Related U.S. Application Data
(60) Provisional application No. 62/045,759, filed on Sep. 4, 2014.

(51) Int. Cl. H01L 31/18; H01L 31/09

(52) U.S. Cl. CPC H01L 31/18; H01L 31/09

(57) ABSTRACT

A planar fixed area thin film antenna-coupled metal-insulator-metal (MIM) rectifier of arbitray metal with a native nickel oxide insulator. Devices can be designed for millimeter wave, IR, NIR and visible wavelengths.

### CROSS REFERENCE TO RELATED APPLICATION

This application claims the benefit of co-pending U.S. Provisional Application Ser. No 62/045,759 filed Sep. 4, 2014 entitled “IR Planar Antenna-Coupled Metal-Insulator-Metal Rectifier”, the entire contents of which are hereby incorporated by reference.

### BACKGROUND

1. Technical Field

This invention relates to fabrication of antenna-coupled Metal-Insulator-Metal (MIM) rectennas.

2. Background

The use of Metal-Insulator-Metal (MIM) tunnel diodes as rectennas, or antenna-coupled rectifiers, for energy conversion has been explored with more interest recently. Advances in nanotechnology fabrication have provided increased feature resolution. Devices have been made using symmetric metals (e.g. Ni—NiO—Ni) and asymmetric metals (e.g. Al—AlOx/Pt).

Various antenna designs (e.g. bowtie and dipole) have used deposited oxides as well as native oxides. The metal fabrication process of choice has typically used a two angle directional deposition of the metals through a suspended shadow mask or simply a shadow evaporation technique.

### SUMMARY

A method for fabricating a planar fixed area thin film antenna-coupled metal-insulator-metal rectifier of arbitrary metal with a native nickel oxide insulator is provided.

The preferred fabrication method(s) avoid a problem with prior art methods that require maintaining thickness uniformity of an insulator layer which lies along a right angle contour of an edge of a first metal layer. By instead employing a planar technique using a metal via, this edge effect is alleviated to create a controlled thickness and uniform oxide using a planar process that is superior to previous methods.

The approach improves the repeatability and reliability of the devices, provide a more controllable area, and provide a way to potentially increase asymmetry of the junction via vertical geometric tailoring of the via. Devices can be designed for millimeter wave, infrared (IR), near-infrared (NIR) and visible wavelengths.

### BRIEF DESCRIPTION OF THE DRAWINGS

The description below refers to the accompanying drawings, of which:

FIG. 1 illustrates a sequence of steps to fabricate a MIM diode with a metal post via.

FIG. 2A shows another fabrication sequence with the MIM diode disposed at the junction of a bowtie antenna.

FIG. 2B is a top view of a bowtie-type MIM rectenna.

FIG. 3 shows yet another fabrication sequence resulting in a geometric asymmetric planar MIM diode.

### DETAILED DESCRIPTION OF AN EMBODIMENT

Methods for fabrication of a planar MIM structure using a metal via post are now described.

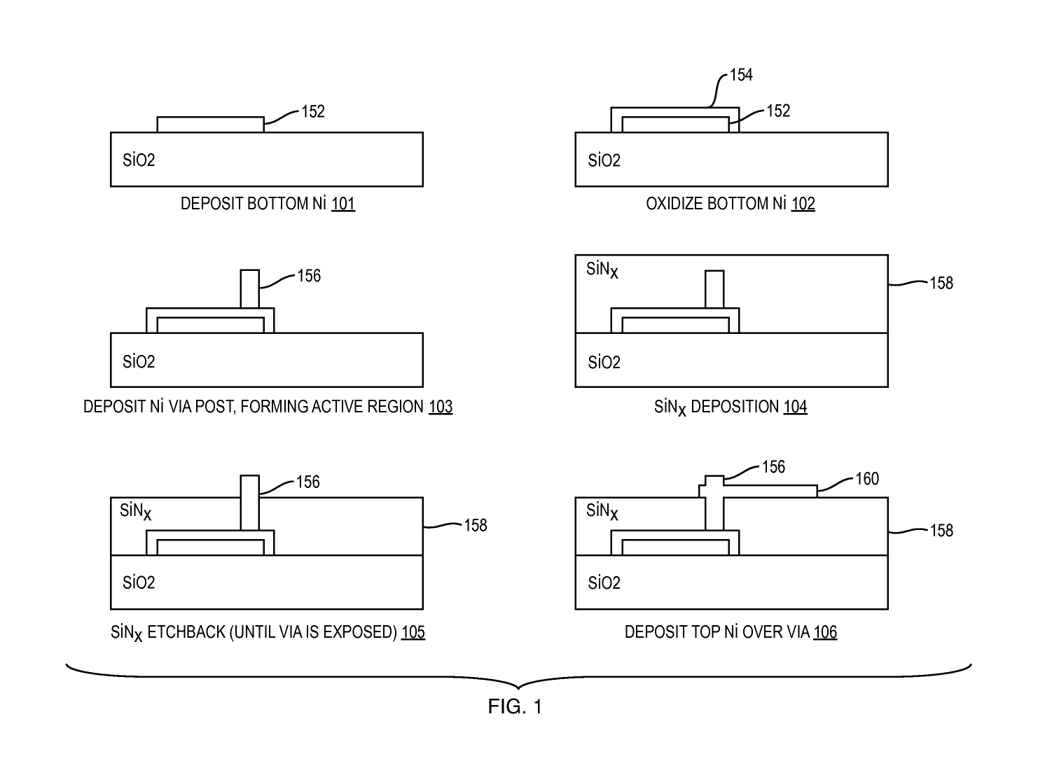

One method as shown in FIG. 1 begins with depositing a post on a native oxide first metal layer, isolating the metal via post with SiNx, and depositing the top metal layer after etching the SiNx to expose the metal via post.

More specifically, at at step 101, a bottom MIM electrode metal such as nickel 152 is deposited on a substrate such as a silicon dioxide (SiO2) substrate 150. The bottom electrode metal 152 may be deposited such as by spin coating a polymethyl methacrylate (PMMA) onto the substrate 150, micro patterning the first MIM electrode 152 such as via an electron beam, developing the PMMA, and then evaporating the nickel layer 152. In the example embodiment shown the nickel electrode 152 is 60 nanometers (nm) thick. The PMMA spincoat step may involve coating two or more PMMA layers (e.g., EL13 and A2 950 K).

In a next step 102 the bottom nickel electrode 152 is oxidized leaving a insulating layer 154.

In step 103 the conductive via post 156 is formed by again spincoating PMMA, patterning the desired desired via shape 156, and evaporating nickel. Example height/diameter ratios for the post 156 may range from 60 nm/20 nm to 60 nm/50 nm. Taller ratios may be preferred to ensure that the oxide layer 154 is covered.

In a next step 104 a silicon nitride (SiNx) (Si₃N₄ being an example) dielectric layer 158 is deposited 158. This layer 158 may be a uniform thickness of 200 nm.

In a next step 105 etchback of this dielectric 158 is done until the via 156 is at least partially exposed. The etchback may be done with a fluorocarbon such as tetrafluoromethane (CF₄). The etching process should ensure that other areas in the MIM structure remain covered.

Finally in step 106 the top MIM electrode 160 is formed by depositing nickel 10 adjacent the via 156. The top electrode160 may be formed in a similar way as the lower electrode 150.

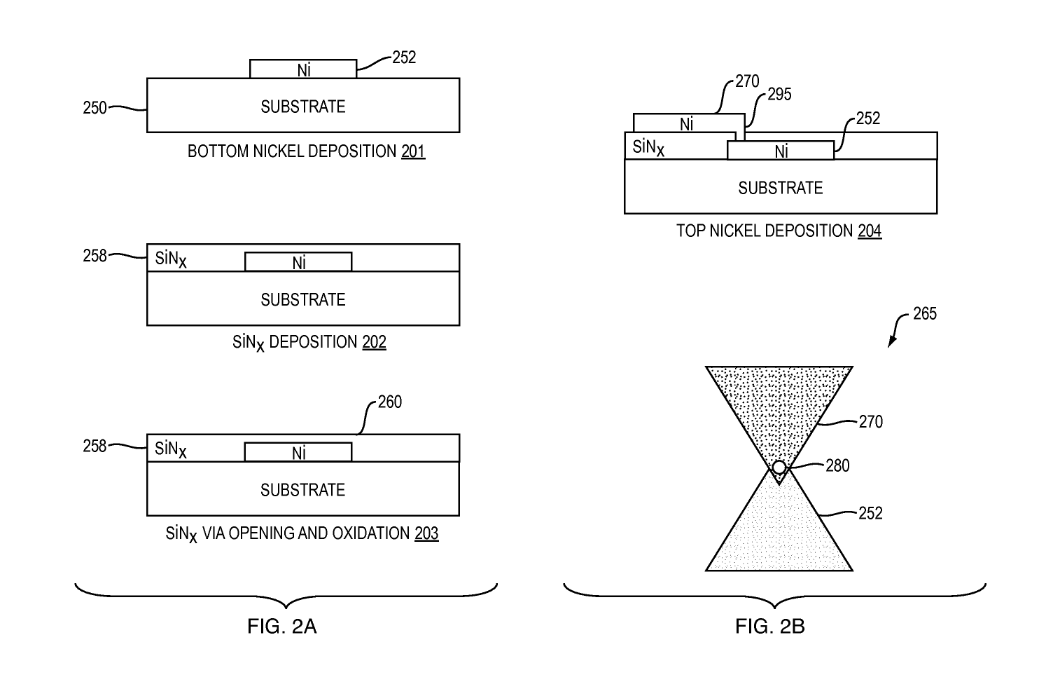

FIG. 2A shows other details for using similar methods to form the metal via by etching an opening in the isolating SiNx and then filling it with a metal. Beginning in step 201 with a substrate 250, nickel is deposited to form the bottom electrode 252, and is covered with SiNx isolating layer in step 202. This may be done as the step 150 in FIG. 1.

In step 203 an opening 260 is etched in the isolating layer 258. Nickel is then deposited in the area adjacent the opening 260 to form both the top electrode 270 and via 295 in a single deposition step. The layer may have a height of 60 nm above the SiNx layer to ensure the via hole 260 is completely plugged.

FIG. 2B is a top view of a bowtie antenna-coupled MIM diode structure formed by any of the processes of FIG. 1, 2A or 3. The bottom electrode and top electrode, each of a triangular shape meet at a point where their vertices overlap at or near the via.

In the method of FIG. 2A, the opening 260 may be formed in step 202 by depositing 100 nm of the isolating material 258 and to cover the vertical sides and horizontal top edges of the bottom electrode 252 and adjacent substrate 250. PMMA may then be spincoated in the desired pattern via e-beam and developed. may be performed HF or BOE (which may need to be diluted to control timing and/or welling of the resulting pattern) may be used for etching in step 203.

Another method of using a trench to deposit the metal via can be extended to creating a top metal structure that has a favorable electron current flow thereby enhancing the asymmetry of the device and increasing the diode rectification efficiency.

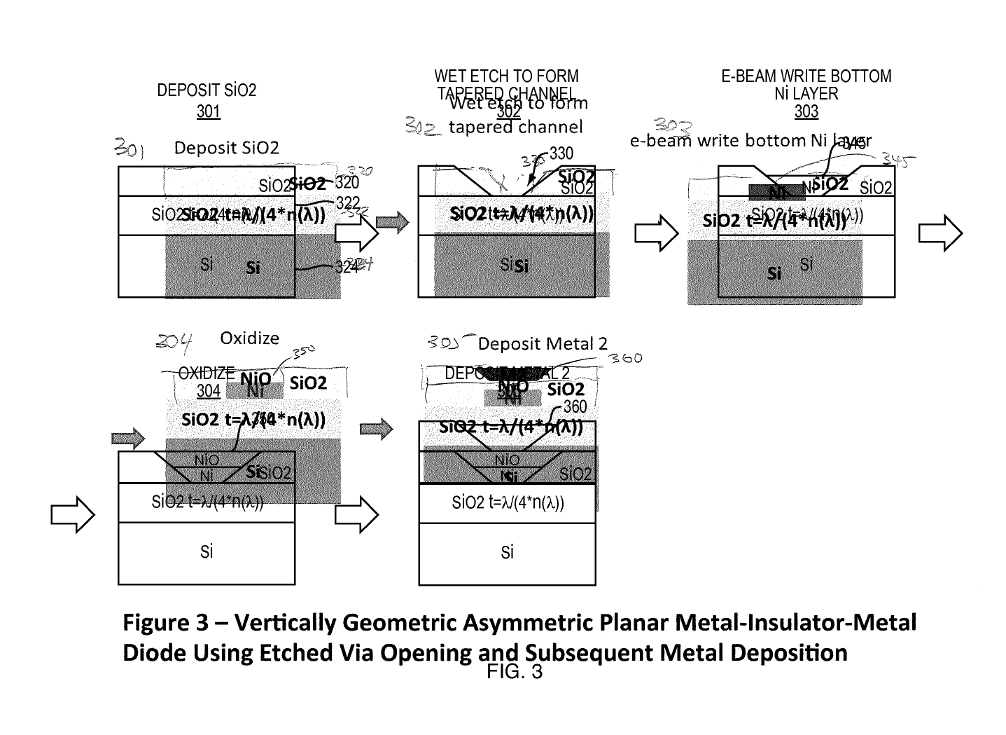

This assymetric geometry is accomplished as shown in FIG. 3, by etching the isolating layer 320 (shown as SiO₂) with a wet etch step to create a trapezoidal (or other tapered) trench that is subsequently filled with the top metal layer.

More specifically, in step 301 silicon dioxide layers 320, 322 are deposited on a silicon substrate 324. In step 302 a wet etch forms a tapered channel 330, which may have a trapezoidal shape. In step 303 a bottom nickel layer 345 is formed within the channel 330. In step 304, the nickel layer 345 is partially oxidized to form a nickel oxide layer 350 on the top thereof. In step 305 a top metal electrode 360 is deposited. The top metal may then have a trapezoidal shape as defined by the previous wet etch in step 302.

Horizontal geometric diodes with triangular shapes have been shown to increase diode asymmetry [See U.S. Patent Publication 2011/0017284], but the ability to make this horizontal type of junction with a repeatable process has not been proven. Also, the diodes here are made from only one (1) material and rely solely on the geometry to provide asymmetry of current flow. Here, we also use standard Complementary Metal Oxide Semiconductor (CMOS) processing techniques to make the formation of planar vertical geometrically asymmetric MIM tunnel diode.

Initial planned fabrication efforts use a symmetric Ni—NiO—Ni diode, and then dissimilar metals (e.g. Ni and platinum (Pt) or gold (Au). Initial antenna design is a bowtie at a design wavelength of 10.6 um as per the lower right hand corner of FIG. 2B.

We have now described planar formation of a metal-native oxide-metal layer stack by the use of metal vias. Additionally we described a trapezoidal trench process to enhance the directionality of the electron flow to create a diode with higher rectification efficiency.

What is claimed is:

1. A method for fabricating a metal-insulator-metal diode comprising:
depositing a bottom metal layer; forming a native oxide on the metal depositing an insulation layer on the bottom oxidized metal layer;
forming a conductive post disposed within and exposed above the insulator layer; and
depositing a top metal layer.

2. The method of claim 1 additionally comprising:
etching an opening in the insulator layer; and
depositing the post within the opening.

3. The method of claim 2 wherein the step of etching an opening etches a tapered trench.

4. The method of claim 3 wherein the resulting metal-oxide-metal stack is geometrically asymmetric in a horizontal plane.
